(19) United States
(12) Patent Application Publication
(10) Pub. No.: US 2025/0226257 A1
(43) Pub. Date: Jul. 10, 2025

(54) Susceptor For High Temperature Semiconductor Process

(71) Applicant: MiCo Ceramics Ltd., Anseong-si (KR)

(72) Inventors: Mina Cho, Anseong-si (KR); Sangyub Lee, Anseong-si (KR)

(21) Appl. No.: 19/013,944

(22) Filed: Jan. 8, 2025

(30) Foreign Application Priority Data
Jan. 9, 2024 (KR) 10-2024-0003252

(51) Int. Cl. H01L 21/687; H01L 21/683

(52) U.S. Cl. CPC H01L 21/68757; H01L 21/6833; H01L 21/68785

(57) ABSTRACT

The present disclosure provides a susceptor. The susceptor includes: a base member including a first cooling gas flow path configured to introduce a cooling gas; a thermal insulation member having a thermal conductivity of 20 W/mK or less, the thermal insulation member including a second cooling gas flow path in communication with the first cooling gas flow path and being stacked on the base member; and an insulating plate stacked on the thermal insulation member, the insulating plate including a plurality of gas holes in communication with the second cooling gas flow path and configured to discharge the cooling gas to cool a substrate.

### CROSS-REFERENCE TO RELATED APPLICATION(S)

This application is based on and claims priority under 35 U.S.C. 119 to Korean Patent Application No. 10-2024-0003252, filed on Jan. 9, 2024, in the Korean Intellectual Property Office, the disclosure of which is herein incorporated by reference in its entirety.

### BACKGROUND OF THE INVENTION

### 1. Field of the Invention

The present disclosure relates to a susceptor, and more particularly, to a susceptor for supporting a substrate in a high-temperature semiconductor process.

### 2. Description of the Prior Art

Semiconductor devices and display devices are manufactured by laminating and patterning multiple thin film layers, including dielectric layers and metal layers, on a glass substrate, a flexible substrate, or a semiconductor wafer substrate through semiconductor processing such as chemical vapor deposition (CVD), physical vapor deposition (PVD), ion implantation, and etching processes. In a chamber for performing these semiconductor processes, a susceptor is used to support various substrates such as a glass substrate, a flexible substrate, and a semiconductor wafer substrate, and a representative example of the susceptor is an electrostatic chuck (ESC) that uses electrostatic force to fix a substrate.

FIG. 1 is a schematic view illustrating an example of a conventional electrostatic chuck.

Referring to FIG. 1, the electrostatic chuck includes a base 20 and an insulating plate 10 on the base.

The insulating plate 10 may be formed of a ceramic material such as alumina. Electrodes 14, such as a DC electrode, a heater electrode, and/or an RF electrode, may be embedded in the insulating plate 10.

To uniformly cool a substrate on the insulating plate 10, a predetermined cooling structure is provided in the base 20 and the insulating plate 10 bonded thereto. Cooling gas introduced through a cooling gas flow path 22 in the base 20 flows through gas holes 12 of the insulating plate 10, which communicate with the cooling gas flow path, to cool the substrate. In such a conventional electrostatic chuck structure, the base 20 and the insulating plate 10 are bonded by an adhesive layer 30.

Semiconductor device manufacturing processes employing such an electrostatic chuck are progressing toward continuously increasing the aspect ratio of devices by stacking ultra-fine patterns in multiple layers.

In semiconductor processes, forming high-aspect-ratio patterns requires an increase in plasma voltage and process time. In particular, for NAND processes with 200 or more layers, the application of a highly durable hard mask is essential. Accordingly, as boron-doped amorphous carbon layers and silicon oxynitride, which exhibit excellent plasma resistance, are being adopted as next-generation hard mask materials, the difficulty of etching processes for hard mask layers is increasing.

To improve reactivity and selectivity in the etching processes for hard mask layers, electrostatic chucks have to operate at a high temperature of 300° C. or higher. However, since organic materials such as silicone are used as adhesives for bonding the ceramic and metal body in conventional electrostatic chucks, the adhesives deteriorate and decompose at high temperatures, thus making it impossible to maintain adhesion at process temperatures.

In addition, conventional electrostatic chucks exhibit a high difference in the coefficient of thermal expansion between the ceramic and metal base. Consequently, very large stress is generated in the adhesive layer between the base and the plate during high-temperature processes.

Meanwhile, in order to increase the temperature, the electrostatic chuck to suit high-temperature processes, it is desirable to use a material with high thermal conductivity, such as AlN. However, AlN has an extremely high thermal conductivity of up to 180 W/m·K, which makes it impossible to control temperature by defining separate heating regions within the electrostatic chuck.

### SUMMARY OF THE INVENTION

In view of the foregoing, the present disclosure provides a susceptor structure capable of suppressing the deterioration of the junction between an insulating plate and a base in high-temperature processes.

The present disclosure also provides a susceptor that is based on a non-adhesive structure between an insulating plate and a base, making it suitable for application in high-temperature processes.

The present disclosure also provides a susceptor that uses an AlN material with high thermal conductivity as a ceramic material while having a structure capable of individually controlling the temperature of multiple heating zones.

Consequently, the present disclosure provides a susceptor including: a base member including a first cooling gas flow path configured to introduce a cooling gas; a thermal insulation member having a thermal conductivity of 20 W/mK or less, the thermal insulation member including a second cooling gas flow path in communication with the first cooling gas flow path and being stacked on the base member; and an insulating plate stacked on the thermal insulation member, the insulating plate including a plurality of gas holes in communication with the second cooling gas flow path and configured to discharge the cooling gas to cool a substrate.

In the present disclosure, the thermal insulation member may be made of quartz, or may contain a material selected from the group consisting of Kovar, Ti, and Hastelloy.

In the present disclosure, the thermal insulation member may be a rigid plate.

In the present disclosure, the base member may be made of a metal matrix composite (MMC) or aluminum.

In the present disclosure, the insulating plate may have a thermal conductivity of 50 W/mK or less at 300° C. In this case, the insulating plate may be made of aluminum nitride, and may further contain Mg and Ti. In this case, the Mg content in the aluminum nitride may be 1 to 3 wt % in terms of MgO conversion, and the Ti content may be 0.1 to 0.5 wt % in terms of TiO₂ conversion.

In the present disclosure, the thermal insulation member preferably has a thermal conductivity of 20 W/mK or less at 300° C.

In the present disclosure, the thermal insulation member preferably has a coefficient of thermal expansion of 10 μm/mK or less at 300° C.

In the present disclosure, a first surface of the thermal insulation member in contact with the base member and a second surface of the thermal insulation member in contact with the insulating plate may each include an outer O-ring disposed along an outer periphery of a stacked structure.

In the present disclosure, the susceptor may further include a plurality of fastening mechanisms coupling the stacked structure by penetrating through the stacked structure in a vertical direction at the outer periphery of the stacked structure. The outer O-ring may be disposed inward of the plurality of fastening mechanisms.

In the present disclosure, the susceptor may include gas holes in the insulating plate to cool a substrate on the insulating plate, and the gas holes may communicate with cooling gas communication holes of the base member.

In the present disclosure, the thermal insulation member may include a first surface in contact with the base member and a second surface in contact with the insulating plate, and an O-ring to seal the second cooling gas flow path is disposed on the first surface and the second surface of the thermal insulation member.

According to the present disclosure, it is possible to provide a susceptor structure capable of suppressing the deterioration of the junction between a ceramic and a base in high-temperature processes. In addition, according to the present disclosure, it is possible to provide a susceptor that uses an AlN material with high thermal conductivity as a ceramic material while having a structure capable of individually controlling the temperature of multiple heating zones.

### BRIEF DESCRIPTION OF THE DRAWINGS

The above and other aspects, features, and advantages of the present disclosure will be more apparent from the following detailed description taken in conjunction with the accompanying drawings, in which;

FIG. 1 is a schematic view illustrating a conventional susceptor structure; and

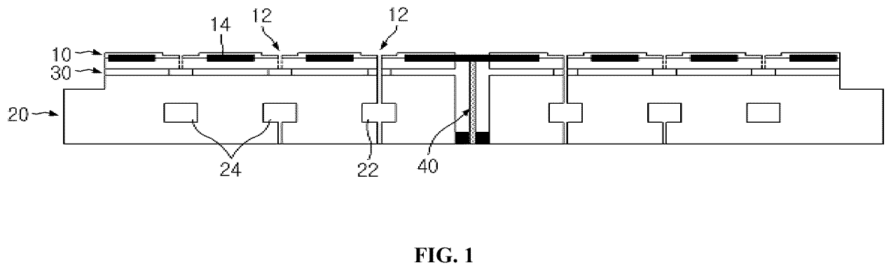

FIG. 2 is a view schematically illustrating a susceptor structure according to an embodiment of the present disclosure.

### DETAILED DESCRIPTION OF THE EXEMPLARY EMBODIMENTS

Unless otherwise defined, all technical and scientific terms used in this specification have the same meaning as commonly understood by a person ordinarily skilled in the art to which the present disclosure pertains. In general, the nomenclature used herein is well known and commonly used in the art.

Throughout the specification, when a part is described as “including” a component, it means that the part may further include other components, unless specifically stated otherwise, rather than excluding them. In this specification, the expression “being made a material A” means not only consisting of only the material A, but also being mixed with materials other than the material A or allowing use of materials obtained by synthesizing materials other than the material A while including the material A as a main component (a component equal to or greater than 50% by weight). In the present disclosure, “stacked” may refer to a state in which two adjacent layers are in direct contact or a state in which they are not in contact with each other with another layer interposed therebetween.

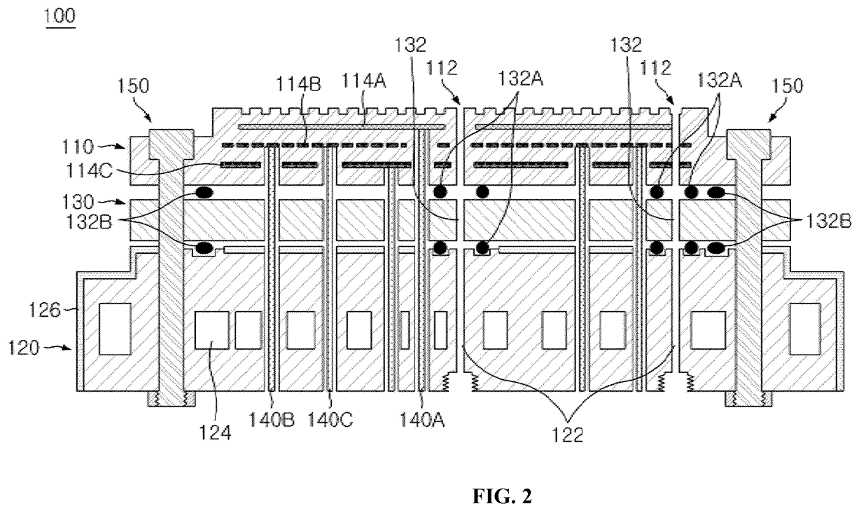

FIG. 2 is a cross-sectional view illustrating a structure of an electrostatic chuck 100 according to an embodiment of the present disclosure.

Referring to FIG. 2, a susceptor according to an embodiment of the present disclosure includes a stacked structure of an insulating plate 110, a thermal insulation member 130, and a base member 120.

In the present disclosure, the insulating plate 110 is preferably of a circular type, but may be designed in other shapes such as an elliptical or rectangular shape.

In the present disclosure, the insulating plate 110 includes at least one electrode layer therein. For example, the electrode layers may include a chuck electrode layer 114A, a heater electrode layer 114B, and an RF electrode layer 114C, but may, of course, include only some of these electrode layers. In addition, although each electrode layer is illustrated as a single layer, each electrode layer may include two or more layers. Conversely, two or more electrode functions may be integrated into a single electrode layer. Furthermore, an RF voltage may be applied to the base, rather than to the RF electrode layer 114C.

In the present disclosure, the insulating plate 110 may contain at least one material selected from the group consisting of dielectric materials, for example, alumina (Al₂O₃), aluminum nitride (AlN), silicon carbide (SiC), silicon nitride (Si₃N₄), silicon oxide (SiO₂), barium oxide (BaO), zinc oxide (ZnO), cobalt oxide (CoO), tin oxide (SnO₂), zirconium oxide (ZrO₂), yttria (Y₂O₃), and yttrium aluminates such as YAG, YAM, and YAP.

Preferably, in the present disclosure, the insulating plate 110 may be made of an AlN material. Since an insulating plate made of an AlN material generally exhibits very high thermal conductivity, it is difficult to apply in cases where a substrate needs to be divided into multiple heating regions for independent temperature control. The present disclosure allows the use of low-thermal-conductivity AlN as the material of the insulating plate 110.

In the present disclosure, a low-thermal-conductivity AlN plate may be achieved by controlling the amount of sintering additives. Oxygen dissolved in the AlN lattice reduces the thermal conductivity of AlN. Accordingly, by suppressing the content of alkaline earth metals such as Ca and Mg, rare earth metals such as yttrium (Y), and transition metals such as Ti, which are known as sintering additives, it is possible to retain phonon-scattering factors such as oxygen and vacancies in the lattice, thereby enabling the production of a low-thermal-conductivity AlN sintered body. For example, the shaft may be an AlN sintered body containing 2 wt % or less of yttria as a sintering additive, where the thermal conductivity may be controlled by the content of the sintering additive, such as yttria.

More preferably, the AlN plate of the present disclosure may contain Mg and Ti as metal elements. The thermal conductivity of the AlN plate may be reduced by the addition of MgO as a sintering additive. This may be due to the low thermal conductivity of grain boundary phases such as spinel precipitated by the addition of MgO. In addition, TiO₂ added as a sintering aid binds to aluminum vacancies in the AlN lattice, thereby allowing the aluminum vacancies to be retained in the AlN lattice. Accordingly, the thermal conductivity of AlN may be reduced. The addition of MgO and TiO₂ as sintering additives should be at least at a minimum level that has an effective influence, and since an increase in the amount of addition may reach saturation, an appropriate amount should be added. In the present disclosure, the Mg content in the sintered plate may be at least 0.1 wt %, at least 0.5 wt %, or at least 1.0 wt % in terms of MgO conversion, and may be at most 3.0 wt %, at most 2.5 wt %, at most 2.4 wt %, at most 2.3 wt %, at most 2.2 wt %, at most 2.1 wt %, or at most 2.0 wt %. In addition, the Ti content in the sintered plate 110 may be at least 0.05 wt %, at least 0.1 wt %, at least 0.15 wt %, or at least 0.2 wt % in terms of TiO₂. Furthermore, the Ti content in the sintered body may be at most 0.5 wt %, at most 0.4 wt %, at most 0.3 wt %, or at most 0.25 wt %.

In the present disclosure, the plate 110 made of the aforementioned AlN material may have a thermal conductivity of 80 W/mK or less, 70 W/mK or less, 60 W/mK or less, or 50 W/mK or less at a temperature of 300° C. For example, the AlN plate preferably has a thermal conductivity of 40 to 60 W/mK at a temperature of 300° C.

In the present disclosure, the heater electrode layer 114B may be a multi-zone heater partitioned into multiple regions. For example, the heater electrode layer 114B may be a two-zone heater including two concentric heaters, such as an inner heater layer and an outer heater layer, or a multi-zone heater including multiple concentric heater layers. Alternatively, the heater electrode layer 114B may include a multi-zone heater having a sector shape, in which multiple heating zones are radially partitioned.

By applying an AlN plate with relatively low thermal conductivity, the present disclosure enables the implementation of a heater that exhibits different temperatures in partitioned regions even when a multi-zone heater is applied.

Although the insulating plate 110 has been described as having a single body, it may, of course, be formed as a stacked structure including two or more insulating layers (dielectric layers).

In the present disclosure, the electrode layers 114A, 114B, and 114C may be made of a conductive metal material and may be connected to connectors 140A, 140B, and 140C, respectively, so that power can be supplied from the exterior. As an example, the electrode layers 114A, 114B, and 114C may be formed of at least one selected from silver (Ag), gold (Au), nickel (Ni), tungsten (W), molybdenum (Mo), and titanium (Ti), and may be formed of, for example, tungsten (W). In the present disclosure, the electrode layers 114A, 114B, and 114C may be formed through a screen printing process or may be implemented as a metal processed product such as a foil, a coil, or a mesh.

In the present disclosure, the base member 120 may be formed as a multi-layer structure including multiple metal layers. These metal layers may be bonded through a brazing process, a welding process, a bonding process, or the like.

In the present disclosure, the base member 120 may be made of aluminum, an aluminum alloy, or a metal matrix composite (MMC). In the case of MMC, for example, a composite of Al and SiC with a SiC content of 20 to 70 wt % may be used. When MMC is used as the base member as in the present disclosure, the difference in the coefficient of thermal expansion between the base member and the thermal insulation member may be reduced. Accordingly, thermal deformation occurring in the process may be minimized.

In the present disclosure, a ceramic coating layer 126 may be added to the surface of the base member 120 to enhance thermal insulation properties and reduce thermal conductivity. For example, Al₂O₃, Y₂O₃, or a compound thereof may be formed on the surface of the base material by atmospheric plasma spray coating.

A thermal insulation member 130 is interposed between the insulating plate 110 and the base member 120.

The thermal insulation member 130 suppresses heat transfer between the insulating plate 110 and the base 120. Preferably, the thermal insulation member is implemented with a material having a low thermal conductivity material and a low thermal expansion coefficient. In the present disclosure, the thermal insulation member 130 may be a solid rigid plate. In the present disclosure, preferably, the thermal insulation member 130 may have a thickness of 5 to 20 mm.

In the present disclosure, the thermal insulation member 130 preferably has a thermal conductivity of 20 W/mK or less, 15 W/mK or less, 10 W/mK or less, or 5 W/mK or less. The thermal insulation member preferably has a coefficient of thermal expansion of 15 μm/mK or less, 10 μm/mK or less, or 5 μm/mK or less.

For example, the thermal insulation member is preferably implemented with one material selected from the group consisting of Kovar, titanium, Hastelloy, and quartz. More preferably, the thermal insulation member may be implemented with quartz.

The physical properties of the aforementioned thermal insulation member are shown in Table 1 below.

TABLE 1

| | Thermal conductivity | Thermal expansion coefficient |
|---|---|---|
| Classification | (W/m · K,@300° C.) | (μm/mK, @300° C.) |
| Quartz | 1.5 | 0.5 |
| Kovar | 19 | 5.1 |
| Titanium | 19.4 | 8.4 |
| Hastelloy | 15 | 12.8 |
| Aluminum (Ref.) | 160 | 25.2 |

In the present disclosure, the susceptor includes a cooling mechanism for cooling a substrate by introducing a cooling gas such as He. The cooling mechanism may be implemented by a cooling gas flow path that allows communication among the plate, the thermal insulation member, and the base member.

In the present disclosure, the base member 120 includes a first cooling gas flow path 122 configured to introduce a cooling gas from the exterior. The first cooling gas flow path 122 communicates with gas holes 112 of the insulating plate through a second cooling gas flow path 132 of the thermal insulation member stacked on the base member 120, thereby ejecting the cooling gas toward the substrate.

In the present disclosure, the susceptor includes a pair of O-rings 132A at both ends of the second cooling gas flow path 132 on the top and bottom surfaces of the thermal insulation member to seal the flow of the cooling gas through the cooling gas flow paths. In the present disclosure, the O-rings 132A may be made of a material that exhibits heat resistance at high temperatures of 300° C. or more. For example, an O-ring made of a perfluorinated material with high fluorine content, such as FFKM, which has high thermal resistance, may be used.

Accordingly, airtightness may be stably maintained even in high-temperature processes of 300° C. or higher.

In the present disclosure, the stacked structure including the base member 120, the thermal insulation member 130, and the insulating plate 110 is coupled by a fastening mechanism 150. The fastening mechanism 150 may be based on a conventional screw fastening structure, such as a bolt penetrating vertically through the base member 120, the thermal insulation member 130, and the insulating plate 110, and a nut coupled to the bolt.

The susceptor of the present disclosure includes an outer O-ring 132B to support the stacked structure of the base member, the thermal insulation member, and the plate. The outer O-ring 132B may conform to the contour shape of the insulating plate, and, for example, the O-ring may be a circular ring. As described above, the outer O-ring is also preferably made of a heat-resistant material that is capable of withstanding high temperatures of 300° C. or more, such as an O-ring made of FFKM.

While the present disclosure has been described with reference to exemplary embodiments and drawings, these are provided merely to facilitate a comprehensive understanding of the present disclosure and are not intended to limit the present disclosure to the above embodiments. It will be understood by those ordinarily skilled in the art to which the present disclosure pertains that various modifications and variations may be made without departing from the essential characteristics of the present disclosure. Therefore, the spirit of the present disclosure should not be construed as being limited to the described embodiments, and all technical ideas that are equivalent or equivalent modifications to the scope of the claims should be interpreted as being included within the scope of the present disclosure.

1. A susceptor comprising:
a base member comprising a first cooling gas flow path configured to introduce a cooling gas;
a thermal insulation member having a thermal conductivity of 20 W/mK or less, the thermal insulation member comprising a second cooling gas flow path in communication with the first cooling gas flow path and being stacked on the base member; and
an insulating plate stacked on the thermal insulation member, the insulating plate comprising a plurality of gas holes in communication with the second cooling gas flow path and configured to discharge the cooling gas to cool a substrate,
wherein the susceptor comprises a stacked structure of the base member, the thermal insulation member and the insulating plate, and
wherein a first surface of the thermal insulation member in contact with the base member and a second surface of the thermal insulation member in contact with the insulating plate each comprise an outer O-ring disposed along an outer periphery of the stacked structure.

2. The susceptor of claim 1, wherein the thermal insulation member is made of quartz.

3. The susceptor of claim 1, wherein the thermal insulation member comprises a material selected from a group consisting of Kovar, Ti, and Hastelloy.

4. The susceptor of claim 1, wherein the thermal insulation member is a rigid plate.

5. The susceptor of claim 1, wherein the base member is made of a metal matrix composite (MMC) or aluminum.

6. The susceptor of claim 1, wherein the insulating plate has a thermal conductivity of 50 W/mK or less at 300° C.

7. The susceptor of claim 6, wherein the insulating plate is made of aluminum nitride.

8. The susceptor of claim 7, wherein the aluminum nitride further comprises Mg and Ti, and
wherein Mg content in the aluminum nitride is 1 to 3 wt % in terms of MgO conversion, and Ti content in the aluminum nitride is 0.1 to 0.5 wt % in terms of TiO₂ conversion.

9. The susceptor of claim 1, wherein the thermal insulation member has a thermal conductivity of 20 W/mK or less at 300° C.

10. The susceptor of claim 1, wherein the thermal insulation member has a coefficient of thermal expansion of 10 μm/mK or less at 300° C.

11. (canceled)

12. The susceptor of claim 1, further comprising:
a plurality of fastening mechanisms coupling the stacked structure by penetrating through the stacked structure in a vertical direction at the outer periphery of the stacked structure,
wherein the outer O-ring is disposed inward of the plurality of fastening mechanisms.

13. The susceptor of claim 1, wherein the thermal insulation member comprises a first surface in contact with the base member and a second surface in contact with the insulating plate, and
wherein an O-ring to seal the second cooling gas flow path is disposed on the first surface and the second surface of the thermal insulation member.
